(19) United States
(12) Patent Application Publication
(10) Pub. No.: US 2026/0266932 A1
(43) Pub. Date: Sep. 10, 2026

(54) PERMANENT MAGNET MOTOR DEMAGNETIZATION TESTING STATION

(71) Applicant: GM Global Technology Operations LLC, Detroit, MI (US)

(72) Inventors: Alireza Fatemi, Canton, MI (US); Erik Brandon Golm, Sterling Heights, MI (US); Peng Peng, Rochester Hills, MI (US); Brian J. Gallert, Lake Orion, MI (US); Le Chang, Shelby Township, MI (US); Jorge Cintron-Rivera, Melbourne, FL (US)

(21) Appl. No.: 19/070,714

(22) Filed: Mar. 5, 2025

(51) Int. Cl. G01R 33/12; G01R 33/00; H01F 13/00; H02K 11/25

(52) U.S. Cl. CPC G01R 33/1215; G01R 33/0064; G01R 33/007; H02K 11/25; H01F 13/006

(57) ABSTRACT

A magnetic rotor testing structure includes a stator defining a shaft and a rotorette mounted on the shaft, wherein an angular position of the rotorette relative to the shaft is configured to be adjustable. A magnetic support is received in the rotorette. The magnetic support includes multiple permanent magnets defining a single permanent magnet rotor pole. An electric current source is electrically connected to the stator, such that a current provided by the electric current source energizes the stator.

### FEDERAL RESEARCH STATEMENT

This invention was made with U.S. Government support under Agreement No. 00045533-01-01:DE-EE0009190 awarded by the Department of Energy. The U.S. Government may have certain rights in this invention.

### INTRODUCTION

The subject disclosure relates to testing and analysis of permanent magnet (PM) rotor designs for PM motors, and more specifically to a testing station design for testing and analyzing PM rotors.

A permanent magnet motor is a type of electric motor that uses permanent magnets for providing a field excitation in a wound armature. The permanent magnets can either be stationary or rotating; interior or exterior to the armature for a radial flux machine or layered with the armature for an axial flux topology.

Accordingly, it is desirable to provide a test fixture that enables faster and more efficient experimental evaluation of demagnetization risks and allows for more sophisticated three dimensional modeling tools for test correlation.

### SUMMARY

In one exemplary embodiment a magnetic rotor testing structure includes a stator defining a shaft and a rotorette mounted on the shaft, wherein an angular position of the rotorette relative to the shaft is configured to be adjustable. A magnetic support is received in the rotorette. The magnetic support includes multiple permanent magnets defining a single permanent magnet rotor pole. An electric current source is electrically connected to the stator, such that a current provided by the electric current source energizes the stator.

In addition to one or more of the features described herein an axial length of the rotorette is limited to at most an axial length of the received magnetic support.

In addition to one or more of the features described herein the electric current source is a direct current (DC) power source, and wherein the DC power source includes an adjustable output current level and duration.

In addition to one or more of the features described herein the electric current source is a polyphase alternative current (AC) power source, wherein the electric current source is connected to the stator via a polyphase power connection including a converter, and wherein the converter converts received AC power to direct current (DC) power.

In addition to one or more of the features described herein a shaft collar is engaged with the shaft and wherein the shaft is prevented from rotating while the shaft collar is in an engaged state.

In addition to one or more of the features described herein a crank is engaged with the shaft and the shaft collar such that rotation of the crank causes rotation of the shaft, and wherein the crank includes an angular alignment feature configured to determine an angular position of the shaft.

In addition to one or more of the features described herein the angular alignment feature includes a set of through holes in the crank and a corresponding set of identifiers on the faceplate.

In addition to one or more of the features described herein the set of identifiers on the faceplate includes pins extending from the faceplate.

In addition to one or more of the features described herein the angular alignment feature includes a digital angle sensor.

In addition to one or more of the features described herein the plurality of permanent magnets within the magnetic support are reconfigurable such that a magnetic configuration of the single permanent magnet rotor pole can be reconfigured.

In addition to one or more of the features described herein the plurality of permanent magnets are removeable from the magnetic support structure.

In addition to one or more of the features described herein, the structure further includes a housing radially surrounding the shaft, the housing including a faceplate at an axial end, wherein the faceplate includes a crank interfaced with the shaft such that rotation of the crank causes rotation of the shaft, and a set of sensors disposed on the housing, the set of sensors including at least one of a thermocouple and an infrared temperature sensor, the at least one of the thermocouple and the infrared temperature sensor is configured to directly measure a temperature of the single permanent magnet rotor pole.

In addition to one or more of the features described herein the housing is disposed within a thermal chamber with the stator being positioned within the thermal chamber, and wherein the thermal chamber is configured to control a thermal environment within the thermal chamber.

In addition to one or more of the features described herein the rotorette comprises a dummy rotor defining a slot configured to receive the magnetic support and at least a first magnet retaining plate axially adjacent the dummy rotor and a second magnet retaining plate axially adjacent the dummy rotor, the first and second magnet retaining plates being disposed at opposite axial ends of the dummy rotor.

In addition to one or more of the features described herein a combination of the dummy rotor and the magnet support are magnetically the same as a rotor to be tested.

In another exemplary embodiment a method for operating a magnetic rotor test includes positioning a single pole configuration of permanent magnets within a magnet support and positioning the magnet support within a test structure. A set of pole data of the single pole configuration is measured prior to applying a demagnetization pulse. A demagnetization pulse is applied using the test structure, and the set of pole data is measured during the demagnetization pulse. The set of pole data of the single pole configuration is measured after applying the demagnetization pulse. The test structure includes a stator defining a shaft and a rotorette mounted on the shaft, wherein an angular position of the rotorette relative to the shaft is configured to be adjustable, a magnetic support received in the rotorette. The magnetic support including a plurality of permanent magnets defining a single permanent magnet rotor pole, and an electric current source electrically connected to the stator, such that a current provided by the electric current source energizes the start.

In addition to one or more of the features described herein the method further includes mapping a magnetic flux of the single permanent magnet rotor pole prior to measuring the set of pole data prior to applying the demagnetization pule and mapping the magnetic flux of the single pole permanent magnet rotor pole piece after measuring the set of pole data of the single pole configuration after applying the demagnetization pulse.

In addition to one or more of the features described herein the method further includes modeling a demagnetization process of the single permanent magnet rotor pole based on accumulated measured sets of pole data.

In addition to one or more of the features described herein the set of pole data includes thermal data measured using at least one of a thermocouple and an infrared temperature sensor.

In addition to one or more of the features described herein the method further includes reiterating applying the demagnetization pulse using the test structure and measuring the set of pole data during the demagnetization pulse, and measuring the set of pole data of the single pole configuration after applying the demagnetization pulse, wherein each iteration is performed at at least one of a different one of a temperature, demagnetization current level, rotor angle and duration of exposure to demagnetization conditions.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is an isometric view of a test fixture for permanent magnet rotors inside of a temperature controlled chamber according to some examples;

FIG. 2A is an isometric view of the test fixture of FIG. 1;

FIG. 2B is an end view of the rotorette support portion of the testing station of FIG. 1;

FIG. 3A is an isometric view a rotorette of the test fixture of FIG. 1 isolated from a remainder to the test fixture;

FIG. 3B is an alternate view of the rotorette of FIG. 3A;

FIG. 3C is a partially disassembled view of the rotorette of FIG. 3A;

FIG. 4 is a schematic of a permanent magnet rotor constructed of multiple pole pieces; and

FIG. 5 is a test method for assessing the demagnetization of permanent magnets in electric machines using the test fixture of FIGS. 1-4.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

As used herein, the term controller refers to a system including at least a processor and a memory, with the system being configured to perform, or cause to be performed, at least one operation. The system can be a dedicated controller including a single purpose processor and memory, a general control including one or more modules for performing the operation, a distributed system including multiple controllers in communication with each other and configured to control the operation, or any similar system.

In one general example, a test fixture for high-fidelity experimental verification of demagnetization performance of rotor segments includes a test configuration that receives a single pole section of the rotor being tested in a high ampere-loading stator with the single pole section being loaded into a dummy rotor (referred to as a rotorette). The single pole section is a ferrous wedge including slots in which permanent magnets can be loaded to provide the magnetic field of the pole section. The rotorette includes a magnetic permeability that matches the magnetic permeability of a fully constructed rotor. The single pole section is one radial arc segment of a full rotor. The full rotor is constructed of multiple instances of the single pole section radially arranged into a complete disc.

Use of a single pole section within the test and constructing the testing station to use only the single pole section, allows removal and analysis of the pole section in between portions of the test and allows for testing different rotor designs and magnet layouts via testing differently arranged pole sections without requiring construction of, or testing and analysis of, a full rotor. The use of singular removable rotor segments further allows incorporation of removable magnet pieces that can enable characterization of the magnet pieces before and after demagnetization pulses are applied in the testing process.

Included within the test fixture are multiple infrared (IR) sensors and thermocouples arranged to directly measure the temperature of the pole section throughout operation of the test as well as before and after the test. In some examples, a mechanical shaft collar is used to lock the rotorette with the pole section in a desired position, thereby allowing a respective angle between the rotor magnetomotive force (MMF) and the stator demagnetizing MMF to be statically maintained throughout the test. In some examples, the rotorette is located with respect to the stator using an electrical alignment followed by manual incremental adjustment using a crank including a manual alignment indicator and/or an electronic angle indicator. The test fixture is powered by a direct current (DC) current supply, and the use of a DC current supply allows the test fixture to avoid contribution of current ripple to demagnetization, further improving the ability of the test fixture to have a tighter control over operational parameters that are critical to the demagnetization testing.

In some examples, the test fixture is utilized to provide a method of assessing the demagnetization of permanent magnets in electric machines. The simplified rotorette configuration within the test fixture reduces test complexity while maintaining high fidelity of the testing data. In one example, a test routine operated by the test fixture measures back EMF characterization vs temperature, demagnetization current level and angle and duration using a three segment test cycle. The demagnetization current level and angle and duration can be measured using any conventional sensing system.

The three-segment test cycle includes: First, spinning the rotorette with pristine (newly manufactured) magnets at a given speed and no load. Second, locking the rotorette in a given position while the stator current is applied at the desired current angle (a demagnetization pulse). Third, spinning the rotorette again at the same speed as in the first cycle at no load. The data gathered during the three segment test cycle is correlated with 3D models of the magnets and their corresponding magnetic fields, including back EMF checks and magnet flux density map comparisons, and a model is generated.

In some examples, the three-segment test cycle can provide further modeling using the testing process by allowing removal of the magnets from the rotorette and/or magnet flux mapping before and after the test, thereby allowing direct testing and modeling of the magnets and their magnetic fields.

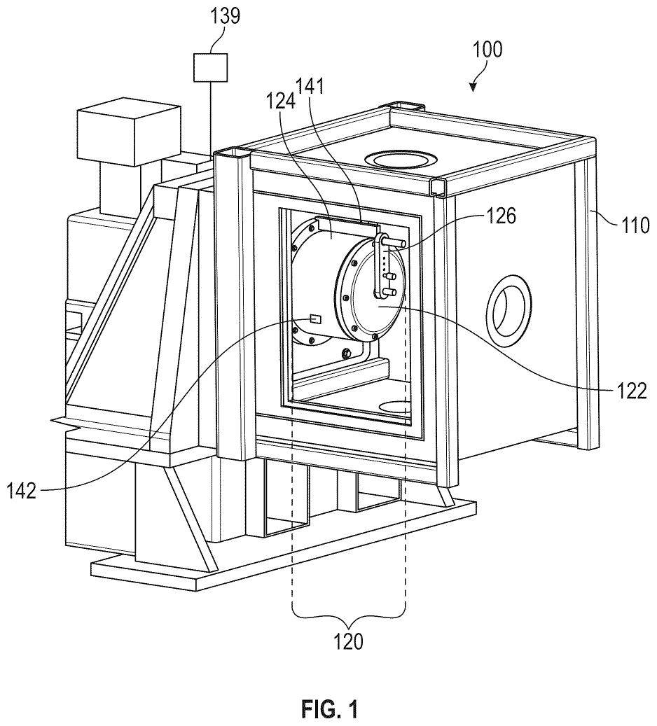

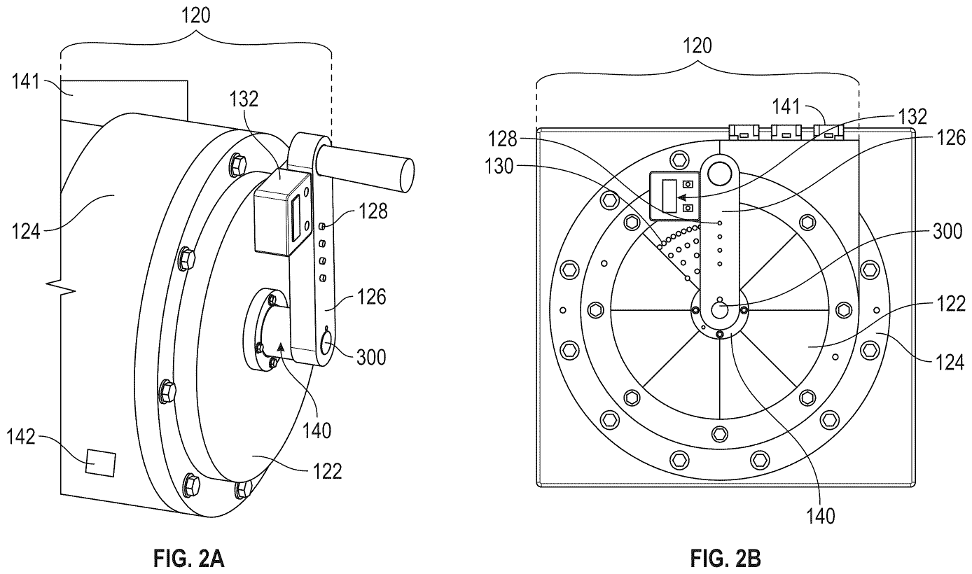

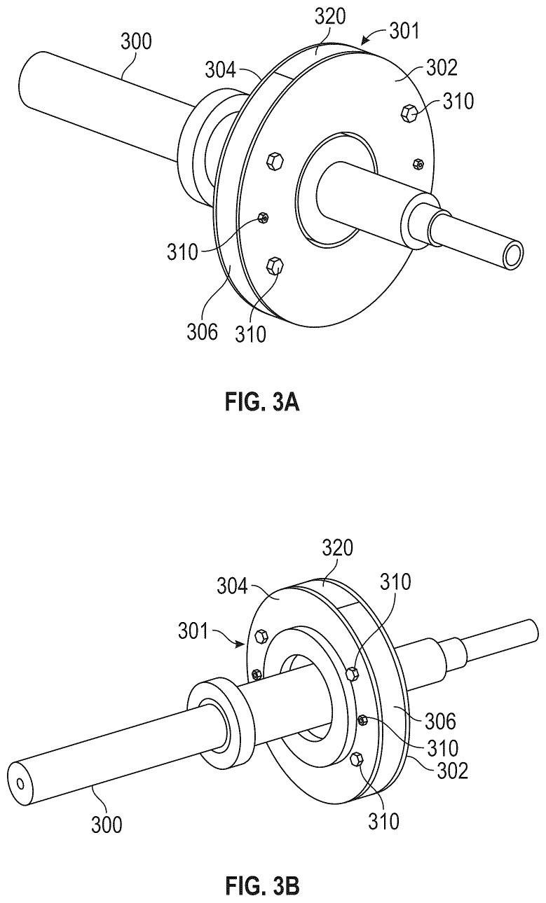

With continued reference to the general system described above, FIG. 1 illustrates an exemplary test fixture 100 according to the general example, with FIGS. 2A and 2B illustrating an isometric view of a support structure 120 (FIG. 2A) and an axial end view of the support structure (120) within a thermal chamber 110 of the test fixture 100. FIGS. 3A, 3B and 3C illustrate a shaft 300, with FIG. 3A illustrating a first isometric view of the shaft, FIG. 3B illustrating a second isometric view of the shaft 300, and FIG. 3C illustrating a partially exploded view of the structures supported on the shaft 300 and of the shaft 300.

Referring collectively to the structures illustrated in FIGS. 1-3C, the test fixture 100 includes a thermal chamber 110 disposed about the support fixture 120. The support fixture 120 supports and retains the shaft 300. Connected to the shaft 300 is the rotorette 301. The rotorette 301 is defined by retaining plates 302, 304 and a dummy rotor 306 illustrated in FIGS. 3A, 3B and 3C. The rotorette 301 receives a magnet support 320 that defines one magnetic pole of a rotor configuration. The one magnetic pole is a singular magnetic pole of a PM rotor design being tested. With continued reference to FIGS. 1-3C, FIG. 4 illustrates a schematic arrangement of pole sections 402 arranged as a complete rotor 400. Referring again to FIGS. 1-3C, in one example, an axial length of the rotor pole magnetic support 320 is equal to the axial length of one magnet for the PM rotor, providing a reduced axial length relative to the rotorette 301.

The support fixture 120 includes non-ferrous faceplates 122 closing an axial end of a cylindrical housing 124. A hand crank 126 extends axially from the shaft 300 and includes one or more angular alignment features configured to determine an angular position of the shaft 300. In one example, the angular alignment feature includes a set of pins 130 extend from the faceplate 122. The pins 130 are configured at precise angular positions on the faceplate 122 such that an operator can turn the hand crank 126 and align openings 128 in the hand crank 126 with certain pins 130, thereby placing the hand crank 126 in a desired angular position.

In some examples, where more precise angular alignment is desired than can be provided by the pins 130, the angular alignment feature can include a digital angle sensor 132 may be further connected to the hand crank 126 and provide a digital reading of the angular position as the hand crank 126 is rotated. It is appreciated that embodiments may exist with either the pins 130, the digital angle sensor 132, or both. In alternate examples, the pins 130 may be colored markings, or other visual indicators, visible through corresponding openings 128 in the hand crank 126. In yet further alternate examples, the pins 130 may be extendible and retractable, such that one or more pins 130 may be extended into or through the corresponding openings 128 in the hand crank 126, further ensuring proper alignment of the shaft 300.

The hand crank 126 is connected to the shaft 300, with the rotorette 301 for the testing being mounted to the shaft as shown in FIGS. 3A, 3B and 3C. In order to lock the shaft 300 in position, a shaft collar 140 is disposed at the connection between the hand crank 126 and the shaft 300. The shaft collar 140 may be engaged with the shaft 300 using any conventional shaft collar configuration and, when engaged, locks the shaft 300 at a precise selected angular position and prevents rotation of the shaft 300. The particular position selected depends on the test being operated and can be selected by one of skill in the art.

In alternate examples, the hand crank 126 may be omitted and any alternative means of rotating the shaft 300 to a desired angular position for the testing process may be utilized in place of the hand crank 126.

A power source 139 provides power to the test structure 100. The power source 139 provides operational power for the test sequence and any necessary power for operating a set of sensors 142. In the illustrated example, the power source 139 is a three phase power source connected to a three phase power connection 141. The three phase power connection 141 includes a converter that converts received three phase power to DC power, and the DC power is used to provide operational power to the test structure 100.

Utilization of a DC power as the operational power simplifies the operations of the test by eliminating controller hardware and associated programing that is used in rotor-level testing. The sensors 142 can include thermocouples, infrared heat sensors, or any combination of the two. The sensors 142 monitor a temperature of the magnet portions within the single rotor pole being tested, and provide additional data.

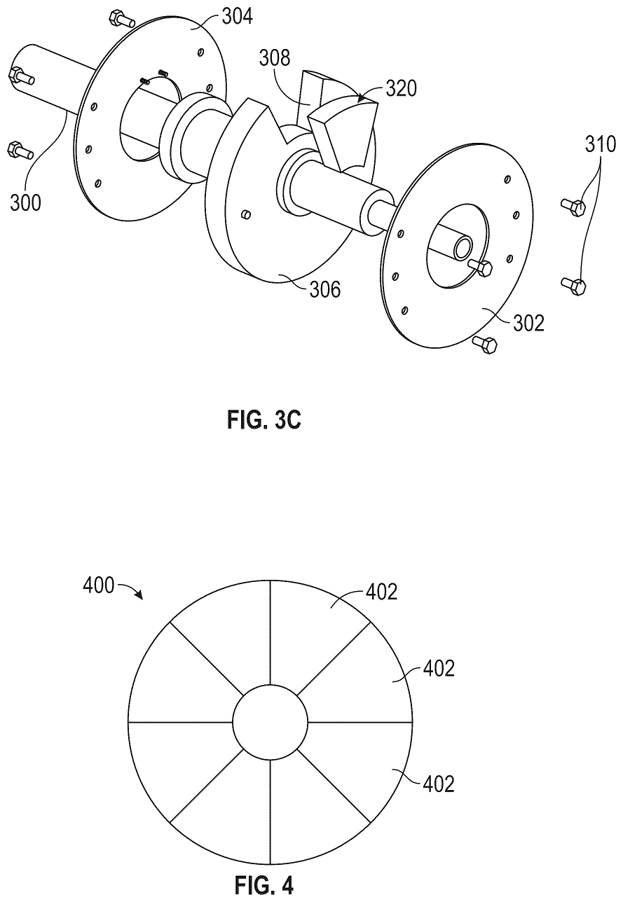

The shaft 300 includes a dummy magnetic rotor 306 with a slot 308 for receiving the magnet support 320. Once installed on the dummy rotor 306, the magnet support 320 is maintained in position by the retaining plates 302, 304 positioned against the axial ends of the dummy rotor 306. The faceplates 302, 304 are maintained in contact with the dummy rotor 306 via a set of fasteners 310 that extend through the faceplates 302, 304 to engage the dummy rotor 306. The faceplates 302, 304 are constructed of a non-ferrous material (e.g. stainless steel) and do not alter the magnetic field of the system rendering them magnetically invisible during the test. The dummy rotor 306 is magnetically permeable and has permeability characteristics similar to, or the same as, a rotor constructed from the pole pieces 402 (e.g. the rotor 400 of FIG. 4).

The shaft 300 and dummy rotor 306 may be, in some examples, a single monolithic component. In other examples, the shaft 300 may include multiple constituent parts assembled to form the shaft 300, and on which the dummy rotor 306 is positioned.

Using the test structure 100, a test can be performed that provides direct temperature measurements of the permanent magnets using the thermocouples and IR sensors. The test routine can include determining back electromagnetic field (EMF) characterization relative to temperature, demagnetization current, angle, and/or duration. In some examples, the test routine generates a magnetic flux map comparison, with the magnetic flux map being able to be mapped directly to a three dimensional model of the permanent magnet structure. The test is also, in some examples, able to determine temperature dependent performance of the magnets and juxtapositions of low and high energy permanent magnet risks. Furthermore, the testing structure 100 is able to provide these analyses under varying operating conditions in order to generate a model correlation.

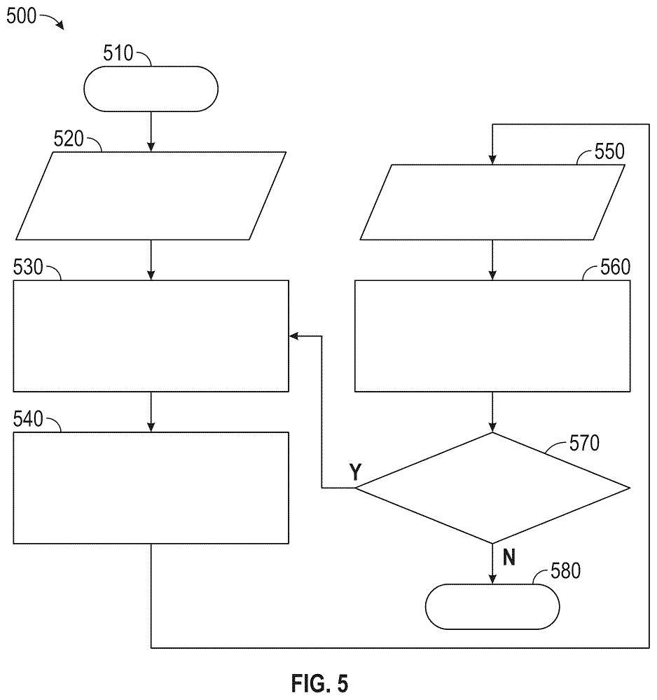

With continued reference to the test structure of FIGS. 1-3C, FIG. 5 illustrates an example process 500 for operating a rotor test using the test structure of FIGS. 1-3C. The process 500 starts at a start position 510 and a permanent magnet rotor design, temperature, demagnetization current and rotor position are determined for the test at a determine parameters step 520.

After determining the testing parameters, initial pre-test measurements of the permanent magnet (PM) flux map, a back emf, and temperatures are measured in a pre-run measurement step 530. The pre-run measurements are determined with pristine magnets (i.e., newly manufacture and unused magnets) spinning at a predetermined speed with no load. The magnet flux map is collected before the insertion of the magnets into the rotor pole.

After pre-measuring the parameters, the process 500 uses the test structure 100 to operate a demagnetization cycle where the rotor 300 is locked in position and a demagnetization pulse is applied to the pole piece 320 in a demagnetization step 540. As the demagnetization pulse is applied, a temperature of the permanent magnets is monitored using the IR sensors and thermocouples in the set of sensors 142. During the demagnetization cycle, the shaft 300 is locked in a single angular position, and the stator current is applied at a desired current angle for the test.

After the demagnetization cycle, the magnets are tested in a post test measurement step 550. The magnets are tested to determined a post test back emf of the magnets and a post test flux map of the magnets. The post test procedures can be any conventional means for determining back EMF and PM flux mapping. During the test magnets step, the shaft 300 is spun at the same speed as in the pre-test measurement at no load using any conventional driver of rotation, allowing the generated post test data to be directly compared to the pretest data. The magnets are removed from the rotorette posttest, for PM flux mapping.

After collecting the post test data, the process 500 performs a model verification step 560, where the results of the post test measurements are compared to a model of the rotor design. If the results agree at a check 570, the process 500 returns to the pre-test measurement step, and testing is iterated until the measurements disagree. If the results disagree, the process 500 ends at an end step 580, and the collected data, including a number of iterations of the process 500 is provided as a data set.

In some examples, the process 500 is iterated multiple times while varying at least one of temperature, demagnetization current level, rotor angle, and duration of exposure to demagnetization conditions.

The data set can then be analyzed using any conventional rotor/magnet analysis. In some examples, the data set may be used to model a demagnetization process using three dimensional simulations and model correlations. In other examples, the data set may be used to evaluation temperature dependent performance of magnets in different rotor designs, including designs using low energy magnets, high energy magnets, or a combination of the two.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A magnetic rotor testing structure comprising:
a stator defining a shaft and a rotorette mounted on the shaft, wherein an angular position of the rotorette relative to the shaft is configured to be adjustable;
a magnetic support received in the rotorette, the magnetic support including a plurality of permanent magnets defining a single permanent magnet rotor pole; and
an electric current source electrically connected to the stator, such that a current provided by the electric current source energizes the stator.

2. The magnetic rotor testing structure of claim 1, wherein an axial length of the rotorette is limited to at most an axial length of the received magnetic support.

3. The magnetic rotor testing structure of claim 1, wherein the electric current source is a direct current (DC) power source, and wherein the DC power source includes an adjustable output current level and duration.

4. The magnetic rotor testing structure of claim 1, wherein the electric current source is a polyphase alternative current (AC) power source, wherein the electric current source is connected to the stator via a polyphase power connection including a converter, and wherein the converter converts received AC power to direct current (DC) power.

5. The magnetic rotor testing structure of claim 1, wherein a shaft collar is engaged with the shaft and wherein the shaft is prevented from rotating while the shaft collar is in an engaged state.

6. The magnetic rotor testing structure of claim 5, wherein a crank is engaged with the shaft and the shaft collar such that rotation of the crank causes rotation of the shaft, and wherein the crank includes an angular alignment feature configured to determine an angular position of the shaft.

7. The magnetic rotor testing structure of claim 6, wherein the angular alignment feature includes a set of through holes in the crank and a corresponding set of identifiers on a faceplate.

8. The magnetic rotor testing structure of claim 7, wherein the set of identifiers on a faceplate includes pins extending from the faceplate.

9. The magnetic rotor testing structure of claim 6, wherein the angular alignment feature includes a digital angle sensor.

10. The magnetic rotor testing structure of claim 1, wherein the plurality of permanent magnets within the magnetic support are reconfigurable such that a magnetic configuration of the single permanent magnet rotor pole can be reconfigured.

11. The magnetic rotor testing structure of claim 1, wherein the plurality of permanent magnets within the magnetic support are removeable and replaceable.

12. The magnetic rotor testing structure of claim 1, further comprising a housing radially surrounding the shaft, the housing including a faceplate at an axial end, wherein the faceplate includes a crank interfaced with the shaft such that rotation of the crank causes rotation of the shaft, and a set of sensors disposed on the housing, the set of sensors including at least one of a thermocouple and an infrared temperature sensor, the at least one of the thermocouple and the infrared temperature sensor is configured to directly measure a temperature of the single permanent magnet rotor pole.

13. The magnetic rotor testing structure of claim 12, wherein the housing is disposed within a thermal chamber with the stator being positioned within the thermal chamber, and wherein the thermal chamber is configured to control a thermal environment within the thermal chamber.

14. The magnetic rotor testing structure of claim 1, wherein the rotorette comprises a dummy rotor defining a slot configured to receive the magnetic support and at least a first magnet retaining plate axially adjacent the dummy rotor and a second magnet retaining plate axially adjacent the dummy rotor, the first and second magnet retaining plates being disposed at opposite axial ends of the dummy rotor.

15. The magnetic rotor testing structure of claim 14, wherein a combination of the dummy rotor and the magnet support are magnetically the same as a rotor to be tested.

16. A method for operating a magnetic rotor test comprising:
positioning a single pole configuration of permanent magnets within a magnet support and positioning the magnet support within a test structure;
measuring a set of pole data of the single pole configuration prior to applying a demagnetization pulse;
applying a demagnetization pulse using the test structure, and measuring the set of pole data during the demagnetization pulse;
measuring the set of pole data of the single pole configuration after applying the demagnetization pulse; and
wherein test structure includes a stator defining a shaft and a rotorette mounted on the shaft, wherein an angular position of the rotorette relative to the shaft is configured to be adjustable, a magnetic support received in the rotorette, the magnetic support including a plurality of permanent magnets defining a single permanent magnet rotor pole, and an electric current source electrically connected to the stator, such that a current provided by the electric current source energizes the stator.

17. The method of claim 16, further comprising mapping a magnetic flux of the single permanent magnet rotor pole prior to measuring the set of pole data prior to applying the demagnetization pulse and mapping the magnetic flux of the single permanent magnet rotor pole after measuring the set of pole data of the single pole configuration after applying the demagnetization pulse.

18. The method of claim 16 further comprising modeling a demagnetization process of the single permanent magnet rotor pole based on accumulated measured sets of pole data.

19. The method of claim 16, wherein the set of pole data includes thermal data measured using at least one of a thermocouple and an infrared temperature sensor.

20. The method of claim 16, further comprising reiterating applying the demagnetization pulse using the test structure and measuring the set of pole data during the demagnetization pulse, and measuring the set of pole data for the single pole configuration after applying the demagnetization pulse, wherein each iteration is performed at least one of a different one of a temperature, demagnetization current level, rotor angle and duration of exposure to demagnetization conditions.
